(19) United States
(12) Patent Application Publication
(10) Pub. No.: US 2026/0304933 A1
(43) Pub. Date: Oct. 1, 2026

(54) SEMICONDUCTOR DEVICE INCLUDING A BURIED PATTERN

(71) Applicant: Samsung Electronics Co., Ltd., Suwon-si (KR)

(72) Inventors: Myeonggyoon Chae, Suwon-si (KR); Junsoo Kim, Suwon-si (KR); Byoung-Gi Kim, Suwon-si (KR); Beomjin Kim, Suwon-si (KR)

(73) Assignee: Samsung Electronics Co., Ltd., Suwon-si (KR)

(21) Appl. No.: 19/437,024

(22) Filed: Dec. 30, 2025

(30) Foreign Application Priority Data
Apr. 1, 2025 (KR) 10-2025-0041916

(51) Int. Cl. H10D 84/83; H10D 62/10; H10D 64/23; H10D 84/01; H10W 20/43

(52) U.S. Cl. CPC H10D 84/832; H10D 64/2565; H10D 84/0151; H10D 62/121; H10W 20/43

(57) ABSTRACT

A semiconductor device includes a first region and a second region, the semiconductor device including a substrate which includes an insulating pattern in the first region, and a first semiconductor pattern in the second region, a separation pattern separating the insulating pattern and the first semiconductor pattern, between the insulating pattern and the first semiconductor pattern, a first active pattern on the insulating pattern, a first gate structure intersecting the first active pattern, a first source/drain region connected to the first active pattern, on a sidewall of the first gate structure, a second active pattern on the first semiconductor pattern, a second gate structure intersecting the second active pattern, a buried pattern on the first semiconductor pattern, a backside wiring structure on the insulating pattern and on the buried pattern and a back source/drain contact penetrating the insulating pattern, and connects the first source/drain region and the backside wiring structure.

### CROSS-REFERENCE TO RELATED APPLICATIONS

This present application claims priority to and the benefit under 35 U.S.C. § 119(a)(d) of Korean Patent Application No. 10-2025-0041916, filed on Apr. 1, 2025, in the Korean Intellectual Property Office, the entire disclosure of which is incorporated herein by reference.

### BACKGROUND

Due to characteristics such as small size, multi-functionality and/or low fabricating cost, semiconductor devices are in the spotlight as important elements in the electronics industry. The semiconductor devices may be classified into semiconductor memory devices that store logical data, semiconductor logic devices that performs computation processing on logical data, hybrid semiconductor devices including memory elements and logical elements, and the like.

As the electronics industry develops to a high level, demands for the characteristics of the semiconductor devices are gradually increasing. For example, the demands for high reliability, high speed and/or multi-functionality of the semiconductor devices are gradually increasing. In order to satisfy such required characteristics, the structures inside the semiconductor device is becoming more and more complex and highly integrated.

On the other hand, as the semiconductor device becomes more and more highly integrated, widths of wiring patterns and via patterns that realize the semiconductor device gradually decrease. For this reason, voltage drops (e.g., IR drop) of the power distribution network (PDN) that supplies the power supply voltage to the integrated circuit have become an important problem.

### SUMMARY

Aspects of the present disclosure provide a semiconductor device in which a logical element region and a passive element region are easily integrated.

Aspects of the present disclosure provide a method for fabricating a semiconductor device in which a logical element region and a passive element region are easily integrated.

According to aspects of the present disclosure, there is provided a semiconductor device which includes a first region and a second region that are different from one another, the semiconductor device comprising a substrate which includes an insulating pattern in the first region, and a first semiconductor pattern in the second region, a separation pattern which separates the insulating pattern and the first semiconductor pattern, between the insulating pattern and the first semiconductor pattern, a first active pattern on an upper surface of the insulating pattern, a first gate structure which intersects the first active pattern, a first source/drain region which is connected to the first active pattern, on a sidewall of the first gate structure, a second active pattern on an upper surface of the first semiconductor pattern, a second gate structure which intersects the second active pattern, a buried pattern on a lower surface of the first semiconductor pattern, a backside wiring structure on a lower surface of the insulating pattern and on a lower surface of the buried pattern and a back source/drain contact which penetrates the insulating pattern, and connects the first source/drain region and the backside wiring structure, wherein the buried pattern includes a liner film extending along profiles of the lower surface of the first semiconductor pattern and the sidewall of the separation pattern, and a buried insulating film on the liner film.

According to aspects of the present disclosure, there is provided a semiconductor device which includes a first region and a second region that are different from one another, the semiconductor device comprising a substrate which includes an insulating pattern in the first region, a semiconductor pattern in the second region, and a field insulating film that covers at least a part of a sidewall of the insulating pattern and at least a part of a sidewall of the semiconductor pattern, a first active pattern on an upper surface of the insulating pattern, a first gate structure which intersects the first active pattern, a source/drain region which is connected to the first active pattern, on a sidewall of the first gate structure, a second active pattern on an upper surface of the semiconductor pattern, a second gate structure which intersects the second active pattern, a buried pattern on a lower surface of the semiconductor pattern, a backside wiring structure on a lower surface of the insulating pattern, a lower surface of the field insulating film, and a lower surface of the buried pattern and a back source/drain contact which penetrates the insulating pattern, and connects the source/drain region and the backside wiring structure, wherein the buried pattern includes a liner film extending along profiles of a lower surface of the semiconductor pattern and a sidewall of the field insulating film, and a buried insulating film on the liner film.

According to aspects of the present disclosure, there is provided a semiconductor device which includes a first region and a second region that are different from one another, the semiconductor device comprising a substrate which includes an insulating pattern in the first region, and a semiconductor pattern in the second region, a first active pattern on an upper surface of the insulating pattern, a first gate structure which intersects the first active pattern, a source/drain region which is connected to the first active pattern, on a sidewall of the first gate structure, a second active pattern on an upper surface of the semiconductor pattern, a second gate structure which intersects the second active pattern, a buried pattern on a lower surface of the semiconductor pattern, a backside wiring structure on a lower surface of the insulating pattern and on a lower surface of the buried pattern and a back source/drain contact which penetrates the insulating pattern, and connects the source/drain region and the backside wiring structure, wherein the second region includes a first sub-region and a second sub-region that are different from one another, and a thickness of the semiconductor pattern of the first sub-region is greater than a thickness of the semiconductor pattern of the second sub-region.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF DRAWINGS

The above and other aspects and features of the present disclosure will become more apparent by describing in detail embodiments thereof with reference to the attached drawings, in which:

FIG. 1 is an example layout diagram for explaining the semiconductor device according to some embodiments.

FIGS. 2 and 3 are schematic cross-sectional views for explaining the semiconductor devices according to some embodiments.

FIGS. 4 to 8 are various schematic cross-sectional views for explaining the semiconductor device according to some embodiments.

FIGS. 9 to 20 are intermediate step diagrams for explaining the method for fabricating the semiconductor device according to some embodiments.

FIG. 21 is an intermediate step diagram for explaining a method for fabricating a semiconductor device according to some embodiments.

FIGS. 22 to 25 are intermediate step diagrams for explaining a method for fabricating a semiconductor device according to some embodiments.

### DETAILED DESCRIPTION OF THE EMBODIMENTS

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In this specification, although only MBCFET® including a multi-bridge channel is shown as an example of electronic elements included in a semiconductor device, this is merely an example. As another example, it goes without saying that the semiconductor device may include a tunneling transistor (tunneling FET), a VFET (Vertical FET), a CFET (Complementary FET) or a three-dimensional (3D) transistor. Alternatively, the semiconductor device may include a bipolar junction transistor, a laterally diffused metal oxide semiconductor (LDMOS), and the like.

Although terms such as first and second are used to describe various elements or components in the present specification, it goes without saying that these elements or components are not limited by these terms. These terms are only used to distinguish a single element or component from other elements or components. Therefore, it goes without saying that a first element or component referred to below may be a second element or component within the technical idea of the present disclosure.

In this specification, the term “same” means not only exactly the same thing, but also includes minute differences that may occur due to a process margin or the like.

The present disclosure relates to a semiconductor device and a method for fabricating the same. More specifically, the present disclosure relates to a semiconductor device including a backside power delivery network (BSPD) and a method for fabricating the same.

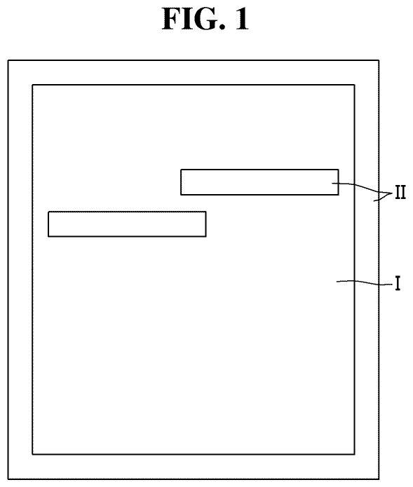

A semiconductor device according to example embodiments will be described below referring to FIGS. 1 to 8.

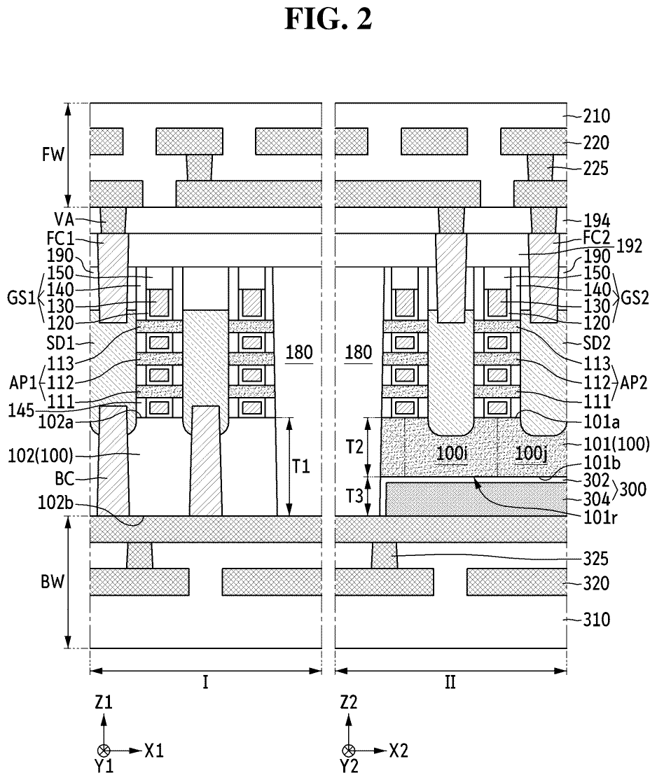

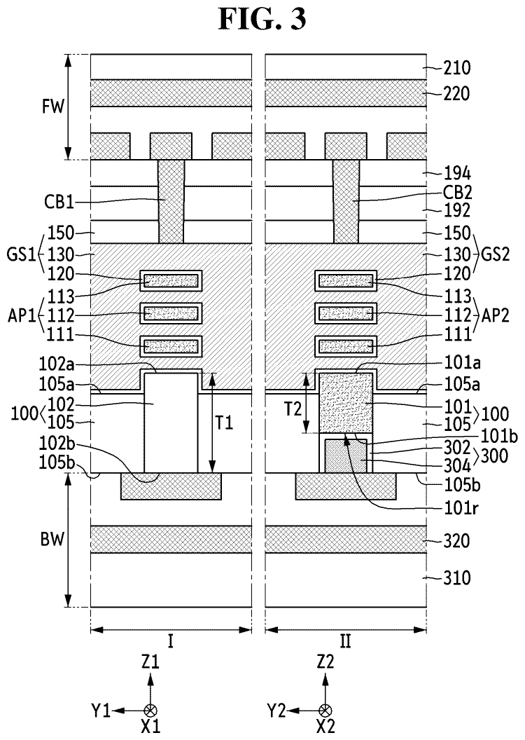

FIG. 1 is an example layout diagram for explaining the semiconductor device according to some embodiments. FIGS. 2 and 3 are schematic cross-sectional views for explaining the semiconductor devices according to some embodiments.

Referring to FIG. 1, the semiconductor device according to some embodiments includes a first region I and a second region II that are different from one another.

The first region I and the second region II may be regions adjacent to one another or may be regions spaced apart from one another. In some embodiments, at least a part of the second region II may surround the periphery of the first region I from viewpoint of a plan view. In some embodiments, a part of the second region II may be disposed inside the first region I from viewpoint of a plan view. The arrangement of the first region I and the second region II is merely example and is not limited to that shown.

The first region I may be a logical element region. For example, the first region I may include one or more logical elements, such as a central processing unit (CPU), a graphics processing unit (GPU), and/or a general logic circuit.

The second region II may be a passive element region. For example, the second region II may include one or more passive elements, such as a resistor, a capacitor, an inductor, a transformer, and/or a diode.

Referring to FIGS. 1 to 3, the semiconductor device according to some embodiments includes a substrate 100, a first active pattern AP1, a second active pattern AP2, a first gate structure GS1, a second gate structure GS2, a first source/drain region SD1, a second source/drain region SD2, an separation pattern 180, a first interlayer insulating film 190, a second interlayer insulating film 192, a third interlayer insulating film 194, a first source/drain contact FC1, a second source/drain contact FC2, a first gate contact CB1, a second gate contact CB2, a front wiring structure FW, a buried pattern 300, a back source/drain contact BC and a backside wiring structure BW.

The substrate 100 may include an insulating pattern 102, a first semiconductor pattern 101, and a field insulating film 105.

The insulating pattern 102 may be formed in a first region I. The insulating pattern 102 may extend long in a first direction X1. The insulating pattern 102 may include a first front side 102a and a first back side 102b that are opposite to one another. For example, in FIGS. 2 and 3, the first front side 102a may be an upper surface of the insulating pattern 102, and the first back side 102b may be a lower surface of the insulating pattern 102.

The insulating pattern 102 may include insulating materials, for example, but are not limited to, at least one of silicon oxide, silicon nitride, silicon oxynitride, silicon oxycarbide, silicon boron nitride, silicon boron carbonitride, silicon oxycarbonitride or a combination thereof. As an example, the insulating pattern 102 may include a silicon oxide film.

The first semiconductor pattern 101 may be formed in the second region II. The first semiconductor pattern 101 may extend long in a second direction X2. The second direction X2 may be the same direction as the first direction X1 or may be different from the first direction X1. The first semiconductor pattern 101 may include a second front side 101a and a second back side 101b that are opposite to one another. For example, in FIGS. 2 and 3, the second front side 101a may be the upper surface of the first semiconductor pattern 101, and the second back side 101b may be the lower surface of the first semiconductor pattern 101.

The first semiconductor pattern 101 may include semiconductor materials, for example, but are not limited to, at least one of silicon, silicon germanium, indium antimonide, lead telluride, indium arsenide, indium phosphide, gallium arsenide, gallium antimonide or a combination thereof.

The field insulating film 105 may be formed in the first region I and the second region II. The field insulating film 105 may cover at least a part of the sidewall of the insulating pattern 102 and at least a part of the sidewall of the first semiconductor pattern 101. The field insulating film 105 may include a third front side 105a and a third back side 105b that are opposite to one another. For example, in FIG. 3, the third front side 105a may be the upper surface of the field insulating film 105, and the third back side 105b may be the lower surface of the field insulating film 105.

The field insulating film 105 may include an insulating material, for example, but is not limited to, at least one of silicon oxide, silicon nitride, silicon oxynitride, silicon oxycarbide, silicon boron nitride, silicon boron carbonitride, silicon oxycarbonitride or a combination thereof. As an example, the field insulating film 105 may include a silicon oxide film.

Although a boundary between the insulating pattern 102 and the field insulating film 105 is shown to exist in FIG. 3, this is only an example. In some cases, there may be no boundary between the insulating pattern 102 and the field insulating film 105.

In some embodiments, the upper part of the insulating pattern 102 may protrude above the field insulating film 105. For example, as shown in FIG. 3, the first front side 102a of the insulating pattern 102 may be disposed to be higher than the third front side 105a of the field insulating film 105.

In some embodiments, the upper part of the first semiconductor pattern 101 may protrude above the field insulating film 105. For example, as shown in FIG. 3, the second front side 101a of the first semiconductor pattern 101 may be disposed to be higher than the third front side 105a of the field insulating film 105.

In some embodiments, the first front side 102a of the insulating pattern 102 and the second front side 101a of the first semiconductor pattern 101 may be located to be coplanar (or at the same level). For example, a height of the first front side 102a of the insulating pattern 102 and a height of the second front side 101a of the first semiconductor pattern 101 may be the same on the basis of the third front side 105a of the field insulating film 105.

In some embodiments, the first back side 102b of the insulating pattern 102 and the third back side 105b of the field insulating film 105 may be disposed to be coplanar (or at the same level).

In some embodiments, the second back side 101b of the first semiconductor pattern 101 may be disposed to be higher than the third back side 105b of the field insulating film 105. For example, the lower part of the field insulating film 105 may protrude below the second back side 101b of the first semiconductor pattern 101.

In some embodiments, a thickness T1 of the insulating pattern 102 may be greater than a thickness T2 of the first semiconductor pattern 101. For example, as shown in FIGS. 2 and 3, the first front side 102a of the insulating pattern 102 and the second front side 101a of the first semiconductor pattern 101 may be located to be coplanar (or at the same level), and the second back side 102b of the insulating pattern 102 may be located to be lower than the second back side 101b of the first insulating pattern 101.

In some embodiments, a thickness T2 of the first semiconductor pattern 101 may be about 50 nm or more. For example, the thickness T2 of the first semiconductor pattern 101 may be about 50 nm to about 200 nm, about 50 nm to about 100 nm, or about 50 nm to about 70 nm. In the above range, the first semiconductor pattern 101 may be provided at a thickness suitable for forming a passive element.

The first active pattern AP1 may be formed in the first region I. The first active pattern AP1 may be formed on the first front side 102a of the insulating pattern 102. The first active pattern AP1 may extend long in the first direction X1.

The second active pattern AP2 may be formed in the second region II. The second active pattern AP2 may be formed on the second front side 101a of the first semiconductor pattern 101. The second active pattern AP2 may extend long in the second direction X2.

Each of the first active pattern AP1 and the second active pattern AP2 may include silicon (Si) or germanium (Ge), which is an elemental semiconductor material. Alternatively, each of the first active pattern AP1 and the second active pattern AP2 may include a compound semiconductor, for example, a group IV-IV compound semiconductor or a group III-V compound semiconductor. The group IV-IV compound semiconductor may be, for example, a binary compound or a ternary compound containing at least two or more of carbon (C), silicon (Si), germanium (Ge), and tin (Sn), or a compound obtained by doping these elements with a group IV element. The group III-V compound semiconductor may be, for example, one of a binary compound, a ternary compound or a quaternary compound formed by combining at least one of aluminum (Al), gallium (Ga), and indium (In) as group III elements with at least one of phosphorus (P), arsenic (As), and antimonium (Sb) as group V elements.

In some embodiments, each of the first active pattern AP1 and the second active pattern AP2 may include a plurality of bridge patterns 111 to 113 spaced apart from the substrate 100. For example, the bridge patterns 111 to 113 of the first active pattern AP1 may be spaced apart from the insulating pattern 102 in a first vertical direction Z1 that intersects the first front side 102a. For example, the bridge patterns 111 to 113 of the second active pattern AP2 may be spaced apart from the first semiconductor pattern 101 in a second vertical direction Z2 that intersects the second front side 101a. The first vertical direction Z1 and the second vertical direction Z2 may be equal to one another. The bridge patterns 111 to 113 may be arranged in sequence along the first vertical direction Z1 or the second vertical direction Z2, and spaced apart from one another. The bridge patterns 111 to 113 may be used as channel regions of MBCFET® including a multi-bridge channel. The number of bridge patterns 111 to 113 included in each of the first active pattern AP1 and the second active pattern AP2 is merely example, and is not limited to that shown.

The first gate structure GS1 may be formed in the first region I. The first gate structure GS1 may be formed on the first front side 102a of the insulating pattern 102 and the third front side 105a of the field insulating film 105. The first gate structure GS1 may intersect the first active pattern AP1. For example, the first gate structure GS1 may extend long in a third direction Y1 that intersects the first direction X1. In some embodiments, the bridge patterns 111 to 113 of the first active pattern AP1 may extend in the first direction X1 and penetrate the first gate structure GS1.

The second gate structure GS2 may be formed in the second region II. The second gate structure GS2 may be formed on the second front side 101a of the first semiconductor pattern 101 and the third front side 105a of the field insulating film 105. The second gate structure GS2 may intersect the second active pattern AP2. For example, the second gate structure GS2 may extend long in a fourth direction Y2 that intersects the second direction X2. In some embodiments, the bridge patterns 111 to 113 of the second active pattern AP2 may extend in the second direction X2 and penetrate the second gate structure GS2.

In some embodiments, each of the first gate structure GS1 and the second gate structure GS2 may include a gate dielectric film 120, a gate electrode 130, a gate spacer 140, and a gate capping film 150.

The gate dielectric film 120 may be stacked on the substrate 100, the first active pattern AP1, and the second active pattern AP2. The gate dielectric film 120 may be interposed between the first active pattern AP1 and the gate electrode 130, and between the second active pattern AP2 and the gate electrode 130. For example, the gate dielectric film 120 may extend along the periphery of each of the bridge patterns 111 to 113. A part of the gate dielectric film 120 may be interposed between the substrate 100 and the gate electrode 130. For example, the gate dielectric film 120 may further extend along the third front side 105a of the field insulating film 105, the upper part of the insulating pattern 102 protruding from the field insulating film 105, and the upper part of the first semiconductor pattern 101 protruding from the field insulating film 105.

The gate dielectric film 120 may include a dielectric material, for example, at least one of silicon oxide, silicon oxynitride, silicon nitride or a high dielectric constant material having a dielectric constant greater than that of silicon oxide. The high dielectric constant material may include, for example, but is not limited to, at least one of hafnium oxide (HfO₂), zirconium oxide (ZrO₂), lanthanum oxide (La₂O₃), aluminum oxide (Al₂O₃), titanium oxide (TiO₂), strontium titanium oxide (SrTiO₃), lanthanum aluminum oxide (LaAlO₃), yttrium oxide (Y₂O₃), hafnium oxynitride (HfOₓN_{y}), zirconium oxynitride (ZrOₓN_{y}), lanthanum oxynitride (La₂OₓN_{y}), aluminum oxynitride (Al₂OₓN_{y}), titanium oxynitride (TiOₓN_{y}), strontium titanium oxynitride (SrTiOₓN_{y}), lanthanum aluminum oxynitride (LaAlOₓN_{y}), yttrium oxynitride (Y₂OₓN_{y}) or combinations thereof.

The gate electrode 130 may intersect the first active pattern AP1 and the second active pattern AP2. Each of the bridge patterns 111 to 113 of the first active pattern AP1 may extend in the first direction X1 and penetrate the gate electrode 130 of the first gate structure GS1. Each of the bridge patterns 111 to 113 of the second active pattern AP2 may extend in the second direction X2 and penetrate the gate electrode 130 of the second gate structure GS2.

The gate electrode 130 may include conductive materials, for example, but are not limited to, at least one of TiN, WN, TaN, Ru, TiC, TaC, Ti, Ag, Al, TiAl, TiAlN, TiAlC, TaCN, TaSiN, Mn, Zr, W, Al or a combination thereof. The gate electrode 130 may be formed by, but is not limited to, a replacement process.

Although the gate electrode 130 is only shown as being a single film, this is merely an example, and it goes without saying that the gate electrode 130 may be a multi-layer film formed by stacking a plurality of conductive films. For example, the gate electrode 130 may include a work function adjustment film for adjusting the work function, and a filling conductive film for filling a space formed by the work function adjustment film. The work function control film may include, for example, at least one of TiN, TaN, TiC, TaC, TiAlC, or a combination thereof. The filling conductive film may include, for example, W or Al.

The gate spacer 140 may extend along the sidewall of the gate electrode 130. Each of the bridge patterns 111 to 113 of the first active pattern AP1 may extend in the first direction X1 and penetrate the gate spacer 140 of the first gate structure GS1. Each of the bridge patterns 111 to 113 of the second active pattern AP2 may extend in the second direction X2 and penetrate the gate spacer 140 of the second gate structure GS2. The gate spacer 140 may include an insulating material, for example, but is not limited to, at least one of silicon oxide, silicon nitride, silicon oxynitride, silicon oxycarbide, silicon boron nitride, silicon boron carbonitride, silicon oxycarbonitride or a combination thereof.

The gate capping film 150 may extend along the upper surface of the gate electrode 130. The gate capping film 150 may include an insulating material, for example, but is not limited to, at least one of silicon oxide, silicon nitride, silicon oxynitride, silicon oxycarbide, silicon boron nitride, silicon boron carbonitride, silicon oxycarbonitride or a combination thereof.

In some embodiments, each of the first gate structure GS1 and the second gate structure GS2 may further include an inner spacer 145. The inner spacer 145 may be formed on a sidewall of the gate electrode 130 between the bridge patterns 111 to 113. The inner spacer 145 may be formed on the sidewall of the gate electrode 130 between the substrate 100 and the bridge patterns 111 to 113. The inner spacer 145 may include an insulating material, for example, but is not limited to, at least one of silicon oxide, silicon nitride, silicon oxynitride, silicon oxycarbide, silicon boron nitride, silicon boron carbonitride, silicon oxycarbonitride or a combination thereof. In some embodiments, the inner spacer 145 may be omitted.

The first source/drain region SD1 may be formed in the first region I. The first source/drain region SD1 may be formed on at least one sidewall (e.g., both sides) of the first gate structure GS1. The first source/drain region SD1 may be connected to the first active pattern AP1. For example, each of the bridge patterns 111 to 113 of the first active pattern AP1 may penetrate the first gate structure GS1, and be connected to the first source/drain region SD1. The first source/drain region SD1 may be separated from the gate electrode 130 of the first gate structure GS1 by the gate dielectric film 120, the gate spacer 140, and/or the inner spacer 145.

In some embodiments, the first source/drain region SD1 may include an epitaxial layer. For example, the first source/drain region SD1 may include an epitaxial pattern that is grown by an epitaxial growth method from the first active pattern AP1.

The second source/drain region SD2 may be formed in the second region II. The second source/drain region SD2 may be formed on at least one sidewall (e.g., both sides) of the second gate structure GS2. The second source/drain region SD2 may be connected to the second active pattern AP2. For example, each of the bridge patterns 111 to 113 of the second active pattern AP2 may penetrate the second gate structure GS2, and be connected to the second source/drain region SD2. The second source/drain region SD2 may be separated from the gate electrode 130 of the second gate structure GS2 by the gate dielectric film 120, the gate spacer 140 and/or the inner spacer 145.

In some embodiments, the second source/drain region SD2 may include an epitaxial layer. For example, the second source/drain region SD2 may include an epitaxial pattern that is grown by an epitaxial growth method from the second active pattern AP2.

The first source/drain region SD1 and the second source/drain region SD2 may have the same conductivity type or may have different conductivity types. When the first source/drain region SD1 and/or the second source/drain region SD2 are provided as source/drain regions of an NFET, each of the first source/drain region SD1 and/or the second source/drain region SD2 may include an N-type impurity (e.g., P, Sb, or As) or an impurity for preventing diffusion of the N-type impurity. When the first source/drain region SD1 and/or the second source/drain region SD2 are provided as source/drain regions of a PFET, each of the first source/drain region SD1 and/or the second source/drain region SD2 may include a P-type impurity (e.g., B, In, Ga, or Al) or an impurity for preventing diffusion of P-type impurity.

In some embodiments, the first semiconductor pattern 101 may include a first impurity region 100i and/or a second impurity region 100j. Each of the first impurity region 100i and/or the second impurity region 100j may be formed by doping the first semiconductor pattern 101 with an N-type impurity (e.g., P, Sb or As) or a P-type impurity (e.g., B, In, Ga or Al), respectively.

The second source/drain region SD2 may be electrically connected to the first impurity region 100i and/or the second impurity region 100j. For example, the second source/drain region SD2 may be in direct contact with the upper surface of the first impurity region 100i and/or the upper surface of the second impurity region 100j. Each of the first impurity region 100i and/or the second impurity region 100j may have the same conductivity type as the second source/drain region SD2, or may have a different conductivity type from the second source/drain region SD2. The first impurity region 100i and/or the second impurity region 100j may be included in a passive element (e.g., a PN junction) formed in the second region II, but is not limited thereto.

In some embodiments, the first impurity region 100i and the second impurity region 100j may have different conductivity types from one another. As an example, the first impurity region 100i may include a P-type impurity, and the second impurity region 100j may include an N-type impurity. The first impurity region 100i and the second impurity region 100j may be joined to one another to form a PN junction in the first semiconductor pattern 101.

The first interlayer insulating film 190 may fill the spaces on the sidewall of the first gate structure GS1 and the sidewall of the second gate structure GS2. The first interlayer insulating film 190 may cover the first source/drain region SD1 and the second source/drain region SD2. The second interlayer insulating film 192 may be formed on the first gate structure GS1, the second gate structure GS2, and the first interlayer insulating film 190. The third interlayer insulating film 194 may be formed on the second interlayer insulating film 192.

Each of the first interlayer insulating film 190, the second interlayer insulating film 192, and the third interlayer insulating film 194 may include, for example, at least one of silicon oxide, silicon nitride, silicon oxynitride, silicon oxycarbide, silicon boron nitride, silicon boron carbonitride, silicon oxycarbonitride or a low dielectric constant material having a lower dielectric constant than silicon oxide. The low dielectric constant material may include, for example, but is not limited to, at least one of FOX (Flowable Oxide), TOSZ (Torene SilaZene), USG (Undoped Silica Glass), BSG (Borosilica Glass), PSG (PhosphoSilica Glass), BPSG (BoroPhosphoSilica Glass), PETEOS (Plasma Enhanced Tetra Ethyl Ortho Silicate), FSG (Fluoride Silicate Glass), CDO (Carbon Doped silicon Oxide), Xerogel, Aerogel, Amorphous Fluorinated Carbon, OSG (Organo Silicate Glass), Parylene, BCB (bis-benzocyclobutenes), SiLK, polyimide, porous polymeric material, and combinations thereof.

The separation pattern 180 may separate the substrate 100 of the first region I from the substrate 100 of the second region II. For example, the separation pattern 180 may be interposed between the insulating pattern 102 and the first semiconductor pattern 101. The insulating pattern 102 and the first semiconductor pattern 101 may be separated by the separation pattern 180.

The separation pattern 180 may include an insulating material, for example, but is not limited to, at least one of silicon oxide, silicon nitride, silicon oxynitride, silicon oxycarbide, silicon boron nitride, silicon boron carbonitride, silicon oxycarbonitride or a combination thereof. As an example, the separation pattern 180 may include a silicon oxide film.

Although FIG. 2 shows that there is a boundary between the insulating pattern 102 and the separation pattern 180, this is only an example. In some cases, there may be no boundary between the insulating pattern 102 and the separation pattern 180.

In some embodiments, the lower surface of the separation pattern 180 may be disposed to be coplanar with (or at the same level as) the first back side 102b of the insulating pattern 102 and/or the third back side 105b of the field insulating film 105. Although the upper surface of the separation pattern 180 is only shown to be located to be coplanar with (or at the same level as) the upper surface of the first gate structure GS1 and/or the upper surface of the second gate structure GS2, this is only an example. The upper surface of the separation pattern 180 may be located to be lower than the upper surface of the first gate structure GS1 and/or the upper surface of the second gate structure GS2, or may be located to be higher than the upper surface of the first gate structure GS1 and/or the upper surface of the second gate structure GS2.

In some embodiments, the second back side 101b of the first semiconductor pattern 101 may be disposed to be higher than the lower surface of the separation pattern 180. For example, the lower part of the separation pattern 180 may protrude below the second back side 101b of the first semiconductor pattern 101.

In some embodiments, the separation pattern 180 may have a tapered shape with a width decreased downward. For example, the width of the separation pattern 180 may gradually decrease toward the backside wiring structure BW. Here, the width refers to the width in a horizontal direction (e.g., the first direction X1 or the second direction X2) that intersects the vertical direction Z1 or Z2. This may be due to the characteristics of the etching process for forming the separation pattern 180.

The first source/drain contact FC1 may be formed on the upper surface of the first source/drain region SD1. The first source/drain contact FC1 may be electrically connected to the first source/drain region SD1. For example, the first source/drain contact FC1 may penetrate the first interlayer insulating film 190 and the second interlayer insulating film 192, and be in direct contact with the upper surface of the first source/drain region SD1.

The second source/drain contact FC2 may be formed on an upper surface of the second source/drain region SD2. The second source/drain contact FC2 may be electrically connected to the second source/drain region SD2. For example, the second source/drain contact FC2 may penetrate the first interlayer insulating film 190 and the second interlayer insulating film 192, and be in direct contact with an upper surface of the second source/drain region SD2.

The first gate contact CB1 may be formed on an upper surface of the first gate structure GS1. The first gate contact CB1 may be electrically connected to the gate electrode 130 of the first gate structure GS1. For example, the first gate contact CB1 may penetrate the gate capping film 150, the second interlayer insulating film 192, and the third interlayer insulating film 194 of the first gate structure GS1, and be in direct contact with an upper surface of the gate electrode 130 of the first gate structure GS1.

The second gate contact CB2 may be formed on an upper surface of the second gate structure GS2. The second gate contact CB2 may be electrically connected to the gate electrode 130 of the second gate structure GS2. For example, the second gate contact CB2 may penetrate the gate capping film 150, the second interlayer insulating film 192, and the third interlayer insulating film 194 of the second gate structure GS2, and be in direct contact with the upper surface of the gate electrode 130 of the second gate structure GS2.

Each of the first source/drain contact FC1, the second source/drain contact FC2, the first gate contact CB1, and the second gate contact CB2 may include a conductive material, for example, at least one of a metal such as cobalt (Co), titanium (Ti), tantalum (Ta), ruthenium (Ru), tungsten (W) or cobalt tungsten phosphide (CoWP); a conductive metal nitride such as titanium nitride (TiN), tantalum nitride (TaN) or tungsten nitride (WN); and/or a silicide such as nickel silicide (NiSi), cobalt silicide (CoSi), tungsten silicide (WSi), titanium silicide (TiSi), niobium silicide (NbSi) or tantalum silicide (TaSi).

The front wiring structure FW may be formed in the first region I and the second region II. For example, the front wiring structure FW may be formed on the third interlayer insulating film 194. The front wiring structure FW may include a front inter-wiring insulating film 210, front wiring patterns 220, and front via patterns 225. The front wiring patterns 220 may form a multi-layer wiring structure inside the front inter-wiring insulating film 210. The front via patterns 225 may interconnect the front wiring patterns 220 in the vertical direction Z1 or Z2. The number of layers, the number, and the arrangement of the front inter-wiring insulating film 210, the front wiring patterns 220, and the front via patterns 225 are merely example, and are not limited to those shown in the drawings.

The front wiring structure FW may be electrically connected to the first source/drain region SD1, the first gate structure GS1, the second source/drain region SD2, and/or the second gate structure GS2. For example, the front wiring patterns 220 and/or the front via patterns 225 may be electrically connected to the first source/drain contact FC1, the first gate contact CB1, the second source/drain contact FC2, and/or the second gate contact CB2.

In some embodiments, a via contact VA which penetrates the third interlayer insulating film 194 may be formed. Each of the first source/drain contact FC1 and/or the second source/drain contact FC2 may be electrically connected to the front wiring patterns 220 through the via contact VA.

A buried pattern 300 may be formed in the second region II. The buried pattern 300 may be formed on the second back side 101b of the first semiconductor pattern 101. The buried pattern 300 may be buried in the substrate 100 of the second region II. For example, a recess 101r may be formed in the substrate 100 by a recess process on the second back side 101b of the first semiconductor pattern 101. The buried pattern 300 may be formed to fill at least a part of the recess 101r.

In some embodiments, at least a part of the recess 101r may be defined by the second back side 101b of the first semiconductor pattern 101 and a sidewall of the separation pattern 180. For example, as shown in FIG. 2, the buried pattern 300 may be in direct contact with the second back side 101b of the first semiconductor pattern 101 and a sidewall of a lower part of the separation pattern 180 that protrudes below the second back side 101b.

In some embodiments, the lower surface of the buried pattern 300 may be disposed to be coplanar with (or at the same level as) the lower surface of the separated pattern 180.

In some embodiments, at least a part of the recess 101r may be defined by the second back side 101b of the first semiconductor pattern 101 and the sidewall of the field insulating film 105. For example, as shown in FIG. 3, the buried pattern 300 may be in direct contact with the second back side 101b of the first semiconductor pattern 101 and the sidewall of the lower part of the field insulating film 105 protruding below the second back side 101b.

In some embodiments, the lower surface of the buried pattern 300 may be located to be coplanar with (or at the same level as) the third back side 105b of the field insulating film 105.

In some embodiments, the thickness T1 of the insulating pattern 102 may be greater than the thickness T3 of the buried pattern 300. For example, as shown in FIGS. 2 and 3, the first back side 102b of the insulating pattern 102 and the lower surface of the buried pattern 300 may be located to be coplanar (or at the same level), and the first front side 102a of the insulating pattern 102 may be located to be higher than the upper surface of the buried pattern 300.

In some embodiments, a sum (T2+T3) of the thickness T2 of the first semiconductor pattern 101 and the thickness T3 of the buried pattern 300 may be equal to the thickness T1 of the insulating pattern 102. For example, as shown in FIGS. 2 and 3, the first front side 102a of the insulating pattern 102 and the second front side 101a of the first semiconductor pattern 101 may be located to be coplanar (or at the same level), and the first back side 102b of the insulating pattern 102 and the buried pattern 300 may be located to be coplanar (or at the same level).

The buried pattern 300 may include an insulating material, for example, but is not limited to, at least one of silicon oxide, silicon nitride, silicon oxynitride, silicon oxycarbide, silicon boron nitride, silicon boron carbonitride, silicon oxycarbonitride or a combination thereof. As an example, the buried pattern 300 may include a silicon nitride film.

In some embodiments, the buried pattern 300 may include a liner film 302 and a filled insulating film 304 that are sequentially stacked in the recess 101r.

The liner film 302 may extend conformally along the profile of the recess 101r. For example, the liner film 302 may conformally extend along the profile of the second back side 101b of the first semiconductor pattern 101, the sidewall of the separation pattern 180, and the sidewall of the field insulating film 105. The liner film 302 may include, for example, but is not limited to, at least one of silicon oxide, silicon nitride, silicon oxynitride, silicon oxycarbide, aluminum oxide or a combination thereof. As an example, the liner film 302 may include an aluminum oxide film.

The buried insulating film 304 may be formed to fill the region of the recess 101r that remains after the liner film 302 is filled. For example, the liner film 302 may be interposed between the first semiconductor pattern 101 and the buried insulating film 304, between the separation pattern 180 and the buried insulating film 304, and between the field insulating film 105 and the buried insulating film 304. The buried insulating film 304 may include, for example, but is not limited to, at least one of silicon oxide, silicon nitride, silicon oxynitride, silicon oxycarbide, silicon boron nitride, silicon boron carbonitride, silicon oxycarbonitride or a combination thereof. As an example, the buried insulating film 304 may include a silicon nitride film.

The back source/drain contact BC may be formed in the first region I. The back source/drain contact BC may not be formed in the second region II. The back source/drain contact BC may be formed on the lower surface of the first source/drain region SD1. The back source/drain contact BC may be electrically connected to the first source/drain region SD1. For example, the back source/drain contact BC may penetrate the insulating pattern 102, and be in direct contact with the lower surface of the first source/drain region SD1.

The back source/drain contact BC includes a conductive material, for example, at least one of a metal such as cobalt (Co), titanium (Ti), tantalum (Ta), ruthenium (Ru), tungsten (W) or cobalt tungsten phosphorus (CoWP); a conductive metal nitride such as titanium nitride (TiN), tantalum nitride (TaN) or tungsten nitride (WN); and/or a silicide such as nickel silicide (NiSi), cobalt silicide (CoSi), tungsten silicide (WSi), titanium silicide (TiSi), niobium silicide (NbSi) or tantalum silicide (TaSi).

The backside wiring structure BW may be formed in the first region I and the second region II. For example, the backside wiring structure BW may be formed under the substrate 100 and the buried pattern 300. The buried pattern 300 may be interposed between the first semiconductor pattern 101 and the backside wiring structure BW. The backside wiring structure BW may include a back inter-wiring insulating film 310, back wiring patterns 320, and back via patterns 325. The back wiring patterns 320 may form a multi-layer wiring structure in the back inter-wiring insulating film 310. The back via patterns 325 may interconnect the back wiring patterns 320 in the vertical direction Z1 or Z2. The number of layers, number, arrangement, and the like of the back inter-wiring insulating films 310, the back wiring patterns 320, and the back via patterns 325 are merely example and are not limited to those shown in the drawings.

The backside wiring structure BW may be electrically connected to the first source/drain region SD1, the first gate structure GS1, the second source/drain region SD2, and/or the second gate structure GS2. For example, the back wiring patterns 320 and/or the back via patterns 325 may be electrically connected to the back source/drain contact BC.

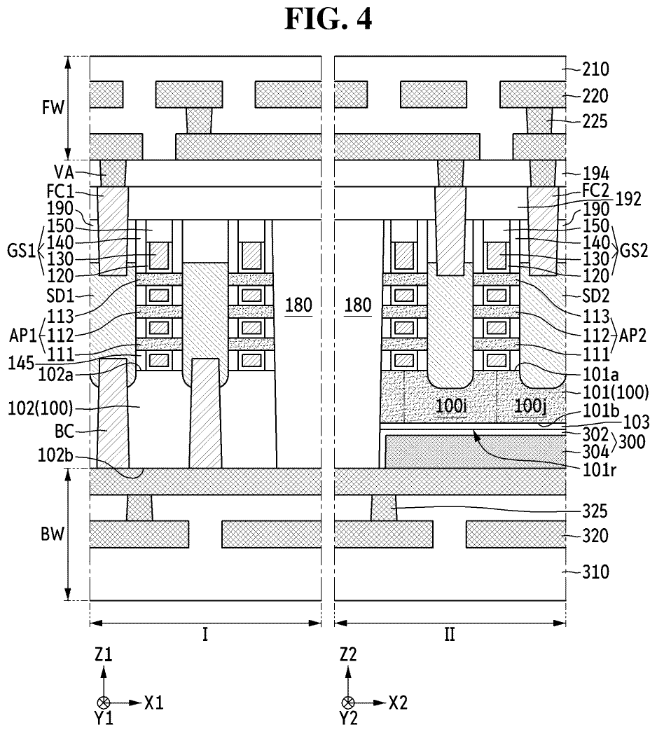

FIGS. 4 to 8 are various schematic cross-sectional views for explaining the semiconductor device according to some embodiments. For convenience of explanation, repeated parts of contents explained above using FIGS. 1 to 3 will be briefly explained or omitted.

Referring to FIG. 4, the semiconductor device according to some embodiments further includes an oxide film 103.

The oxide film 103 may be formed in the second region II. The oxide film 103 may be formed on the second back side 101b of the first semiconductor pattern 101. The oxide film 103 may extend along the second back side 101b of the first semiconductor pattern 101. The oxide film 103 may be interposed between the first semiconductor pattern 101 and the buried pattern 300.

The oxide film 103 may include an oxide of the first semiconductor pattern 101. For example, the oxide film 103 may be formed by oxidizing a part of the first semiconductor pattern 101. As an example, when the first semiconductor pattern 101 is a silicon pattern, the oxide film 103 may include silicon oxide.

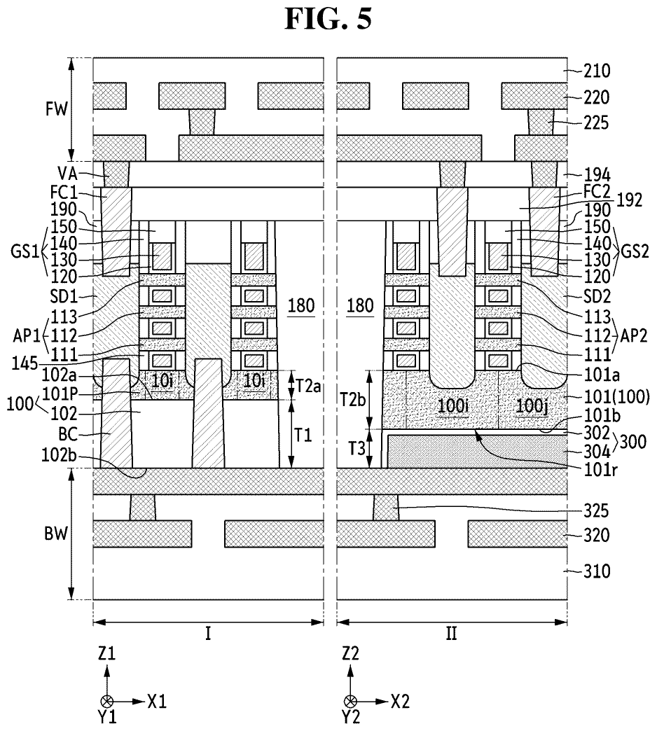

Referring to FIG. 5, in the semiconductor device according to some embodiments, the substrate 100 further includes a second semiconductor pattern 101P.

The second semiconductor pattern 101P may be formed in the first region I. The second semiconductor pattern 101P may extend long in the first direction X1. The second semiconductor pattern 101P may be formed on the first front side 102a of the insulating pattern 102. For example, the second semiconductor pattern 101P may be interposed between the insulating pattern 102 and the first gate structure GS1 in the first vertical direction Z1 and/or between the insulating pattern 102 and the first active pattern AP1 in the first vertical direction Z1. In some embodiments, the bridge patterns 111 to 113 of the first active pattern AP1 may be spaced apart from the second semiconductor pattern 101P in the first vertical direction Z1.

The second semiconductor pattern 101P may include semiconductor materials, for example, but are not limited to, at least one of silicon, silicon germanium, indium antimonide, lead telluride, indium arsenide, indium phosphide, gallium arsenide, gallium antimonide or combinations thereof.

The first semiconductor pattern 101 and the second semiconductor pattern 101P may be formed at the same level. In this specification, the expression “formed at the same level” means formation by the same fabricating process. For example, the first semiconductor pattern 101 and the second semiconductor pattern 101P may have the same material composition.

In some embodiments, the upper surface of the second semiconductor pattern 101P may be disposed to be coplanar with (or at the same level as) the second front side 101a of the first semiconductor pattern 101.

In some embodiments, a thickness T2a of the second semiconductor pattern 101P may be smaller than a thickness T2b of the first semiconductor pattern 101. For example, the upper surface of the second semiconductor pattern 101P may be located to be coplanar with (or at the same level as) the second front side 101a of the first semiconductor pattern 101, and the lower surface of the second semiconductor pattern 101P may be located to be higher than the second back side 101b of the first semiconductor pattern 101.

In some embodiments, the thickness T2a of the second semiconductor pattern 101P may be about 40 nm or less. For example, the thickness T2a of the second semiconductor pattern 101P may be about 1 nm to about 40 nm.

In some embodiments, a sum (T1+T2a) of the thickness T1 of the insulating pattern 102 and the thickness T2a of the second semiconductor pattern 101P may be equal to a sum (T2b+T3) of the thickness T2b of the first semiconductor pattern 101 and the thickness T3 of the buried pattern 300. For example, the upper surface of the second semiconductor pattern 101P and the second front side 101a of the first semiconductor pattern 101 may be located to be coplanar (or at the same level), and the first back side 102b of the insulating pattern 102 and the lower surface of the buried pattern 300 may be located to be coplanar (or at the same level).

In some embodiments, the second semiconductor pattern 101P may include a third impurity region 10i. The third impurity region 10i may overlap at least a part of the first gate structure GS1 in the first vertical direction Z1. The third impurity region 10i may be formed by doping the second semiconductor pattern 101P with an N-type impurity (e.g., P, Sb or As) or a P-type impurity (e.g., B, In, Ga or Al).

The third impurity region 10i may block a leakage current that may occur in the second semiconductor pattern 101P along the first direction X1. As an example, when the first source/drain region SD1 is provided as a source/drain region of an NFET, the third impurity region 10i may include the P-type impurity. As another example, when the first source/drain region SD1 is provided as a source/drain region of a PFET, the third impurity region 10i may include the N-type impurity.

The back source/drain contact BC may penetrate the insulating pattern 102 and the second semiconductor pattern 101P, and be electrically connected to the first source/drain region SD1.

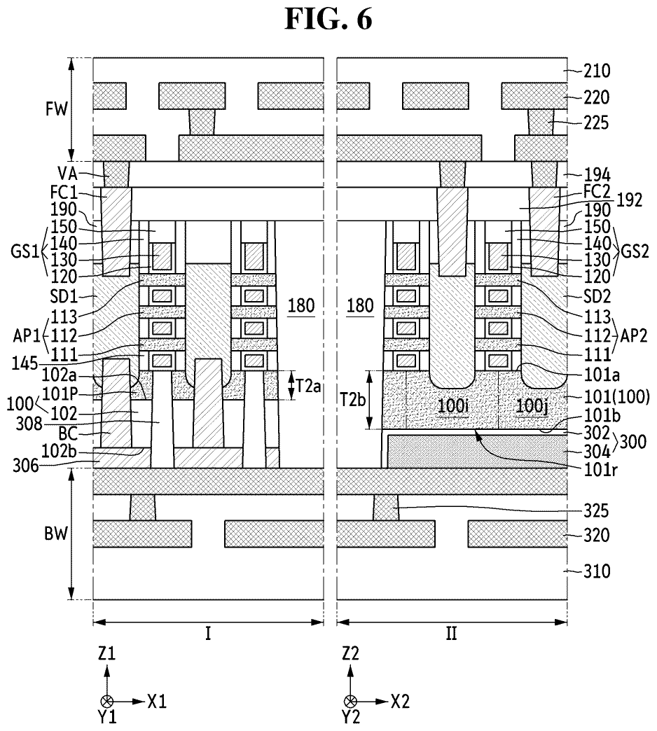

Referring to FIG. 6, the semiconductor device according to some embodiments further includes a second semiconductor pattern 101P, a conductive plate 306, and a cut pattern 308.

The second semiconductor pattern 101P may be formed in the first region I. Since the second semiconductor pattern 101P may be similar to that explained above using FIG. 5, detailed explanation thereof will not be provided below.

The conductive plate 306 may be formed on the first back side 102b of the insulating pattern 102. The conductive plate 306 may be interposed between the back source/drain contact BC and the backside wiring structure BW. The back source/drain contact BC may be electrically connected to the backside wiring structure BW through the conductive plate 306.

The cut pattern 308 may be interposed between the first gate structure GS1 and the backside wiring structure BW. The cut pattern 308 may overlap at least a part of the first gate structure GS1 in the first vertical direction Z1. The cut pattern 308 may extend in the first vertical direction Z1 to cut the conductive plate 306, the insulating pattern 102, and the second semiconductor pattern 101P.

The cut pattern 308 may include, for example, but is not limited to, at least one of silicon nitride, silicon oxynitride, silicon oxycarbide, silicon boron nitride, silicon boron carbonitride, silicon oxycarbonitride and a combination thereof

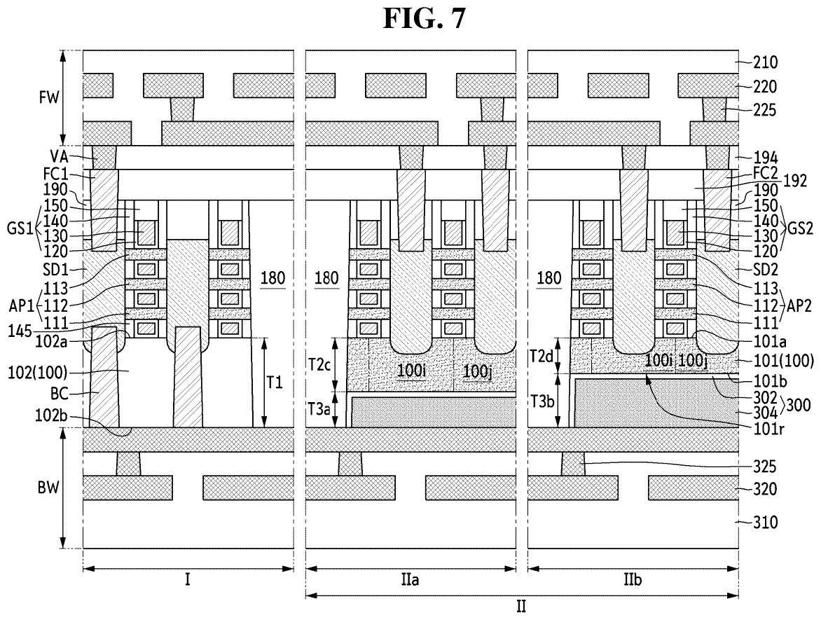

Referring to FIG. 7, in the semiconductor device according to some embodiments, the second region II includes a first sub-region IIa and a second sub-region IIb that are different from one another.

The first sub-region IIa and the second sub-region IIb may be adjacent to one another or may be spaced apart from one another. Each of the first sub-region IIa and the second sub-region IIb may be passive element regions. For example, each of the first sub-region IIa and the second sub-region IIb may include the first semiconductor pattern 101, the field insulating film 105, the second active pattern AP2, the second gate structure GS2, the second source/drain region SD2, the second source/drain contact FC2, the second gate contact CB2, and the buried pattern 300.

The buried pattern 300 of the first sub-region IIa and the buried pattern 300 of the second sub-region IIb may have different thicknesses from one another. For example, a thickness T3a of the buried pattern 300 of the first sub-region IIa may be smaller than a thickness T3b of the buried pattern 300 of the second sub-region IIb. The thickness of the first semiconductor pattern 101 may be adjusted by the thickness of the buried pattern 300. For example, as shown, when the thickness T3a of the buried pattern 300 of the first sub-region IIa is smaller than the thickness T3b of the buried pattern 300 of the second sub-region IIb, a thickness T2c of the first semiconductor pattern 101 of the first sub-region IIa may be greater than a thickness T2d of the first semiconductor pattern 101 of the second sub-region IIb.

In some embodiments, a sum (T2c+T3a) of the thickness T2c of the first semiconductor pattern 101 and the thickness T3a of the buried pattern 300 in the first sub-region IIa may be equal to a sum (T2d+T3b) of the thickness T2d of the first semiconductor pattern 101 and the thickness T3b of the buried pattern 300 in the second sub-region IIb.

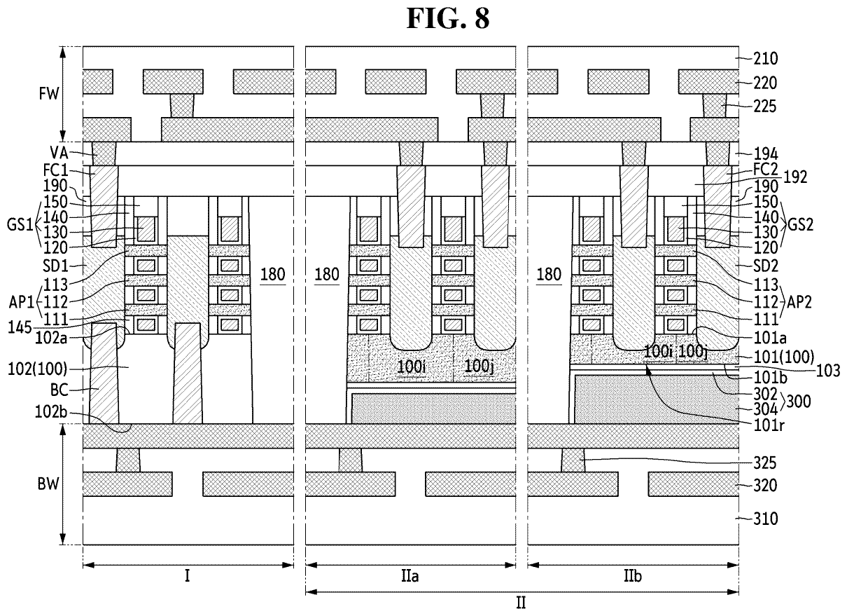

Referring to FIG. 8, the semiconductor device according to some embodiments further includes an oxide film 103.

The oxide film 103 may be formed in each of the first sub-region IIa and the second sub-region IIb. Since the oxide film 103 may be similar to that explained above using FIG. 4, a detailed explanation thereof will not be provided.

Hereinafter, a method for fabricating a semiconductor device according to example embodiments will be described referring to FIGS. 1 to 25.

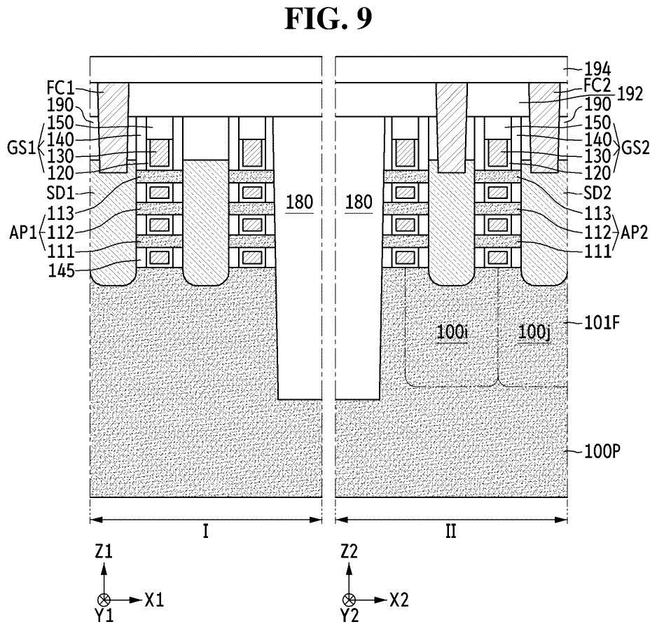

FIGS. 9 to 20 are intermediate step diagrams for explaining the method for fabricating the semiconductor device according to some embodiments. For convenience of explanation, repeated parts of those explained above using FIGS. 1 to 8 will be briefly explained or omitted.

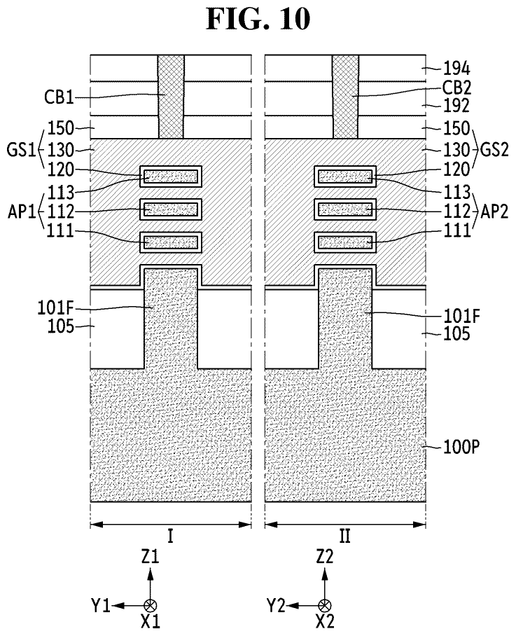

Referring to FIGS. 9 and 10, a base pattern 101F, the field insulating film 105, the first active pattern AP1, the second active pattern AP2, the first gate structure GS1, the second gate structure GS2, the first source/drain region SD1, the second source/drain region SD2, the first interlayer insulating film 190, the separation pattern 180, the second interlayer insulating film 192, the third interlayer insulating film 194, the first source/drain contact FC1, the second source/drain contact FC2, the first gate contact CB1, and the second gate contact CB2 are formed on a base substrate 100P.

The base substrate 100P may be bulk silicon or silicon-on-insulator (SOI). In contrast, the base substrate 100P may be a silicon substrate, or may include other materials, for example, silicon germanium, SGOI (silicon germanium on insulator), SOSG (silicon on silicon germanium), indium antimonide, lead telluride, indium arsenide, indium phosphide, gallium arsenide or gallium antimonide. Or, the base substrate 100P may have an epitaxial layer formed on the base substrate.

The base pattern 101F may protrude from the upper surface of the base substrate 100P. The base pattern 101F of the first region I may extend long in the first direction X1. The base pattern 101F of the second region II may extend long in the second direction X2.

The base pattern 101F may include semiconductor materials, for example, but are not limited to, at least one of silicon, silicon germanium, indium antimonide, lead telluride, indium arsenide, indium phosphide, gallium arsenide, gallium antimonide or a combination thereof. The base pattern 101F may be formed by etching a part of the base substrate 100P, or may be an epitaxial layer grown from the base substrate 100P.

In some embodiments, the base pattern 101F of the second region II may include a first impurity region 100i and/or a second impurity region 100j. Each of the first impurity region 100i and/or the second impurity region 100j may be formed by doping the base pattern 101F of the second region II with an N-type impurity (e.g., P, Sb or As) or a P-type impurity (e.g., B, In, Ga or Al).

The field insulating film 105 may be formed on the base substrate 100P. The field insulating film 105 may cover at least a part of the sidewall of the base pattern 101F. In some embodiments, the upper art of the base pattern 101F may protrude above the field insulating film 105.

The first active pattern AP1 may be formed on the front side (e.g., the upper surface) of the base pattern 101F of the first region I. The second active pattern AP2 may be formed on the front side (e.g., the upper surface) of the base pattern 101F of the second region II. The first gate structure GS1 may intersect the first active pattern AP1. The second gate structure GS2 may intersect the second active pattern AP2. The first source/drain region SD1 is formed on at least one side (e.g., both sides) of the first gate structure GS1, and may be connected to the first active pattern AP1. The second source/drain region SD2 is formed on at least one side (e.g., both sides) of the second gate structure GS2, and may be connected to the second active pattern AP2.

The first interlayer insulating film 190 may fill spaces on the sidewalls of the first gate structure GS1 and the second gate structure GS2. The first interlayer insulating film 190 may cover the first source/drain region SD1 and the second source/drain region SD2. The separation pattern 180 may separate the base pattern 101F of the first region I from the base pattern 101F of the second region II. The second interlayer insulating film 192 may be formed on the first gate structure GS1, the second gate structure GS2, and the first interlayer insulating film 190. The third interlayer insulating film 194 may be formed on the second interlayer insulating film 192.

The first source/drain contact FC1 penetrates the first interlayer insulating film 190 and the second interlayer insulating film 192, and may be connected to the first source/drain region SD1. The second source/drain contact FC2 penetrates the first interlayer insulating film 190 and the second interlayer insulating film 192, and may be connected to the second source/drain region SD2. The first gate contact CB1 penetrates the gate capping film 150, the second interlayer insulating film 192, and the third interlayer insulating film 194 of the first gate structure GS1, and may be connected to the gate electrode 130 of the first gate structure GS1. The second gate contact CB2 penetrates the gate capping film 150, the second interlayer insulating film 192, and the third interlayer insulating film 194 of the second gate structure GS2, and may be connected to the gate electrode 130 of the second gate structure GS2.

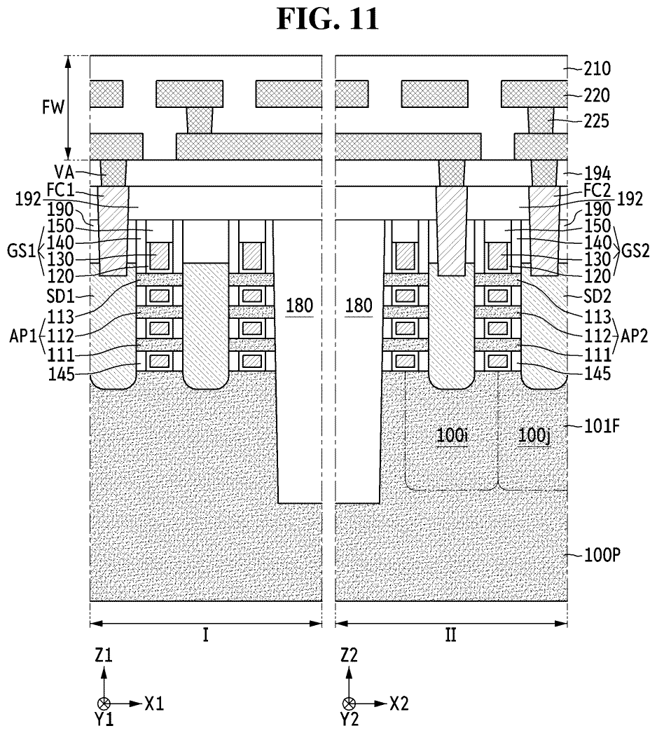

Referring to FIG. 11, a front wiring structure FW is formed.

The front wiring structure FW may be formed on the third interlayer insulating film 194. The front wiring patterns 220 and/or the front via patterns 225 may be electrically connected to the first source/drain contact FC1, the first gate contact CB1, the second source/drain contact FC2, and/or the second gate contact CB2.

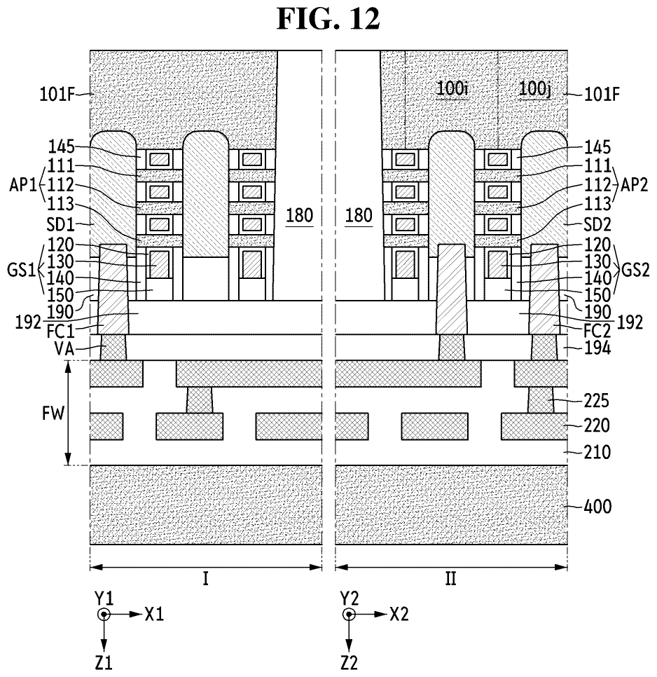

Referring to FIG. 12, a thinning process is performed on the base substrate 100P.

For example, the carrier substrate 400 may be attached onto the result of FIG. 11. After the carrier substrate 400 is attached, the result of FIG. 11 may be inverted. Accordingly, the back side of the base substrate 100P may face upward. A thinning process (e.g., a back grinding process) may then be performed on the back side of the base substrate 100P. As the thinning process is performed, at least a part of the base substrate 100P may be removed.

In some embodiments, the base pattern 101F and/or the field insulating film 105 may be exposed by the thinning process. In some embodiments, the separation pattern 180 may be exposed by the thinning process.

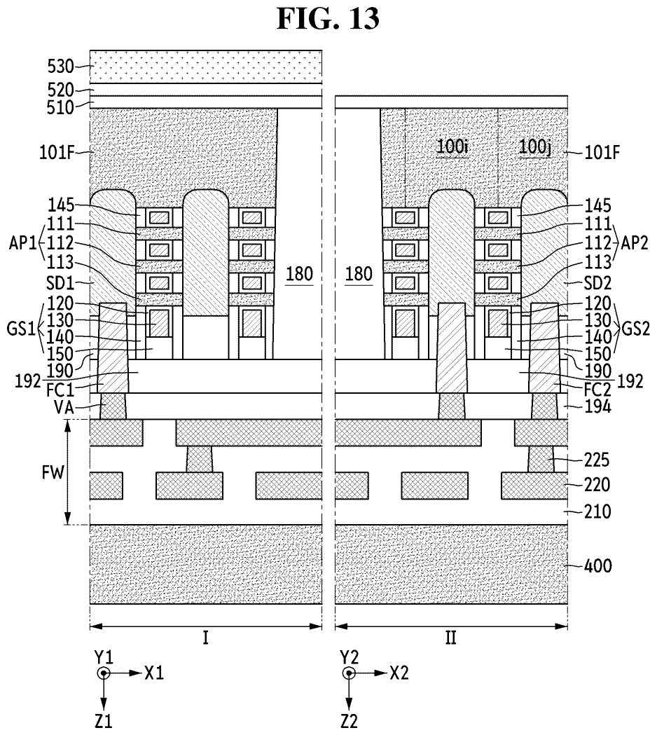

Referring to FIG. 13, a first hard mask film 510, a second hard mask film 520, and a first mask pattern 530 are formed on the back side of the base pattern 101F.

The first hard mask film 510, the second hard mask film 520, and the first mask pattern 530 may be sequentially stacked on the back side of the base pattern 101F. The first mask pattern 530 may be patterned to cover the first region I and expose the second region II. The first mask pattern 530 may include, but is not limited to, a photoresist pattern. Next, a patterning process of patterning the second hard mask film 520 using the first mask pattern 530 as an etching mask may be performed. Accordingly, the second hard mask film 520 may cover the first hard mask film 510 of the first region I, and expose the first hard mask film 510 of the second region II.

The first hard mask film 510 and the second hard mask film 520 may have different etching selectivities from one another. As an example, the first hard mask film 510 may include a silicon oxide film, and the second hard mask film 520 may include a silicon nitride film.

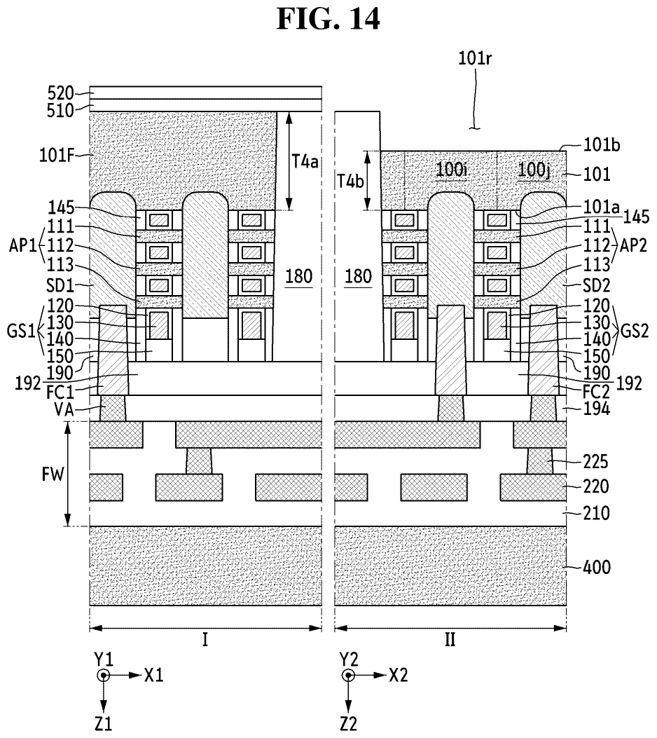

Referring to FIG. 14, a first recess process is performed on the base pattern 101F of the second region II.

For example, an etching process of using the second hard mask film 520 as an etching mask may be performed. As the first recess process is performed, a recess 101r may be formed in the base pattern 101F of the second region II. In addition, the base pattern 101F of the second region II including the recess 101r may form the first semiconductor pattern 101 of the second region II. As a result, a thickness T4b of the first semiconductor pattern 101 of the second region II may become smaller than a thickness T4a of the base pattern 101F of the first region I.

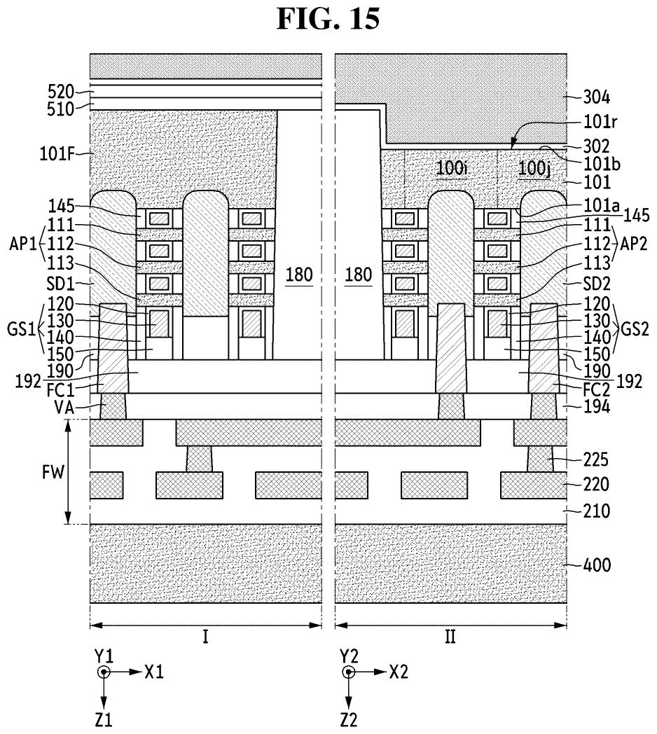

Referring to FIG. 15, the liner film 302 and the buried insulating film 304 are formed.

The liner film 302 and the buried insulating film 304 may be sequentially stacked on the second hard mask film 520 of the first region I and the first semiconductor pattern 101 of the second region II. The liner film 302 and the buried insulating film 304 may fill at least a part of the recess 101r. For example, the liner film 302 may conformally extend along the profile of the recess 101r. The liner film 302 may alleviate or treat defects of the first semiconductor pattern 101 that may occur by the first recess process. The buried insulating film 304 may fill the region of the recess 101r that remains after the liner film 302 is filled.

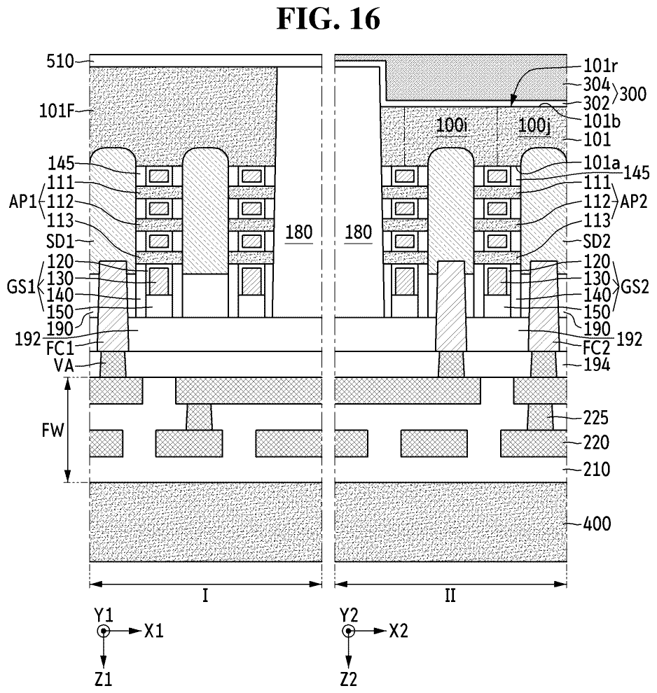

Referring to FIG. 16, the liner film 302 and the buried insulating film 304 of the first region I are removed.

For example, a planarization process may be performed on the first region I and the second region II. The planarization process may include, but is not limited to, a chemical mechanical polishing process. As the planarization process is performed, the first hard mask film 510 may be exposed. Accordingly, the liner film 302 and the buried insulating film 304 of the first region I may be removed. Also, a buried pattern 300 that fills at least a part of the recess 101r may be formed in the second region II.

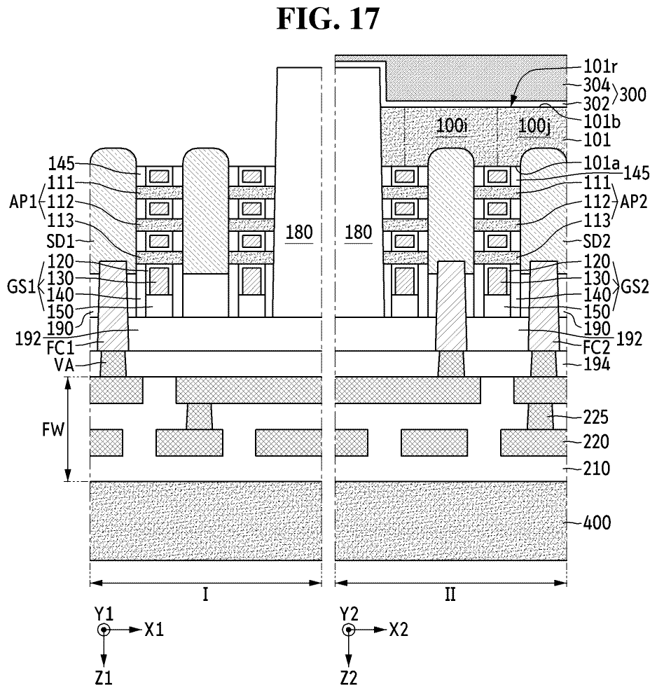

Referring to FIG. 17, a second recess process is performed on the base pattern 101F of the first region I.

For example, an etching process of using the buried pattern 300 as an etching mask may be performed. As the second recess process is performed, at least a part of the base pattern 101F of the first region I may be removed. In some embodiments, the first source/drain regions SD1 may be exposed by the second recess process, as shown. In some embodiments, the base pattern 101F of the first region I may be completely removed by the second recess process, as shown.

In some embodiments, unlike the shown example, after the second recess process is performed, a part of the base pattern 101F of the first region I may remain. Accordingly, the base pattern 101F of the first region I may form the second semiconductor pattern 101P explained above using FIGS. 5 and 6.

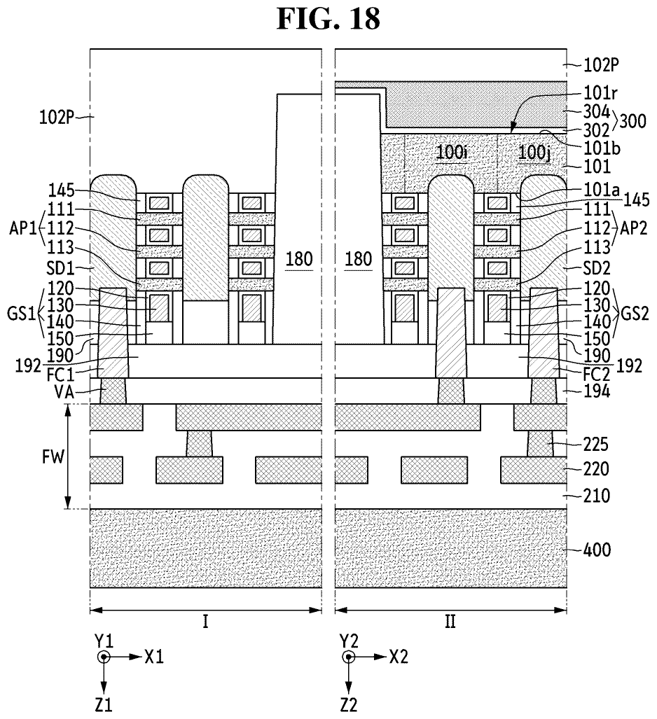

Referring to FIG. 18, a filling insulating film 102P is formed.

The filling insulating film 102P may be formed in the first region I and the second region II. The filling insulating film 102P may fill at least a part of the region of the base pattern 101F removed by the second recess process.

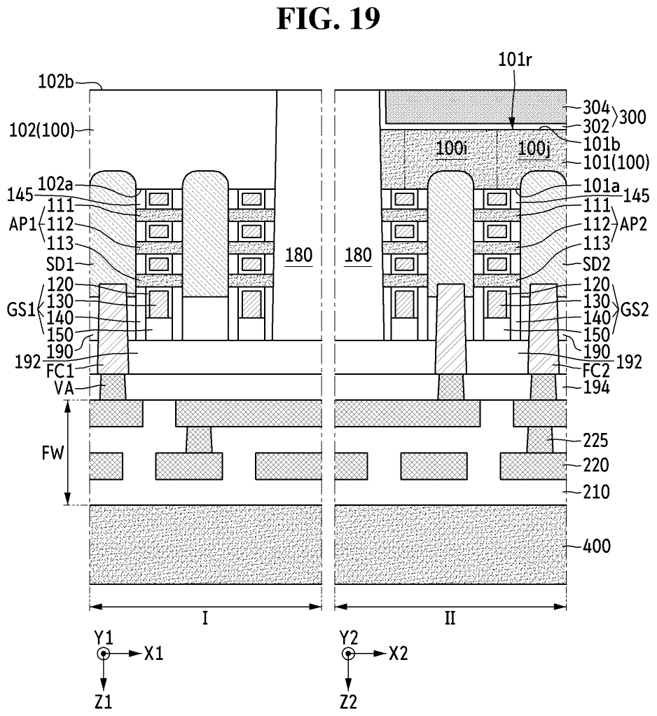

Referring to FIG. 19, the filling insulating film 102P of the second region II is removed.

For example, a planarization process may be performed on the first region I and the second region II. The planarization process may include, but is not limited to, a chemical mechanical polishing process. As the planarization process is performed, the buried pattern 300 may be exposed. Accordingly, the filling insulating film 102P of the second region II may be removed. Also, an insulating pattern 102 which replaces at least a part of the region of the base pattern 101F removed by the second recess process may be formed in the first region I.

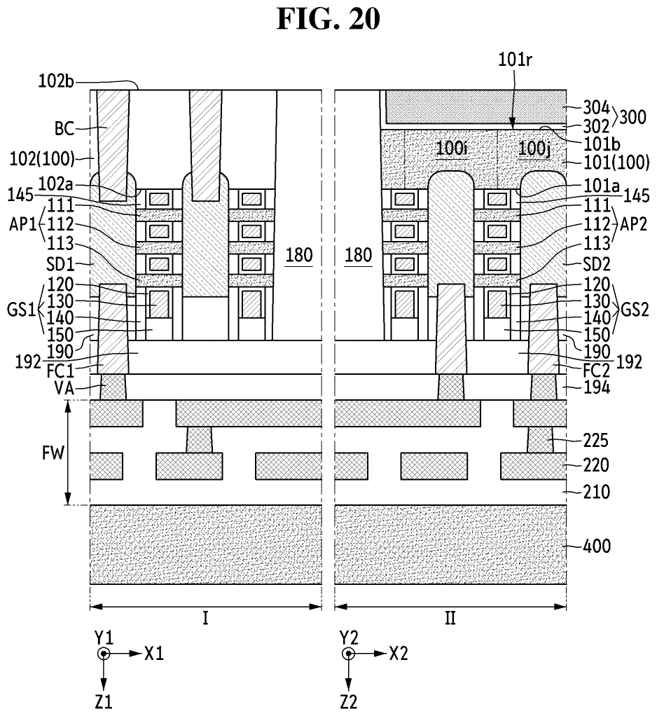

Referring to FIG. 20, a back source/drain contact BC is formed.

The back source/drain contact BC penetrates the insulating pattern 102, and may be connected to the first source/drain region SD1.

Next, referring to FIG. 2, a backside wiring structure BW is formed. Accordingly, the semiconductor device explained above using FIGS. 1 to 3 may be fabricated.

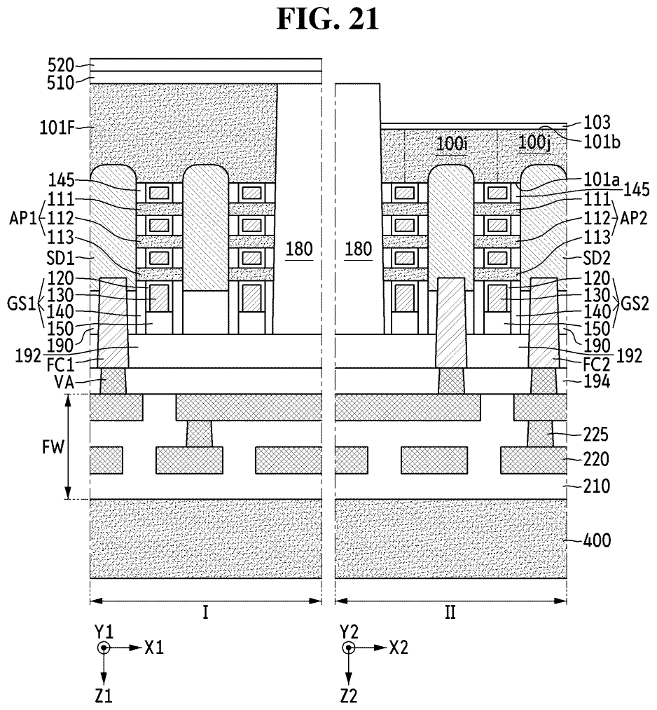

FIG. 21 is an intermediate step diagram for explaining a method for fabricating a semiconductor device according to some embodiments. For convenience of explanation, repeated parts of those explained above using FIGS. 1 to 20 will be briefly explained or omitted. For reference, FIG. 21 is an intermediate step diagram for explaining steps after FIG. 14.

Referring to FIG. 21, a cleaning process is performed on the second back side 101b of the first semiconductor pattern 101.

For example, an oxygen plasma ashing (O₂ plasma ashing) process and a DHF (Dilute Hydrofluoric Acid) treatment process may be sequentially performed on the second back side 101b of the first semiconductor pattern 101. Accordingly, impurities and residues on the second back side 101b of the first semiconductor pattern 101 may be removed. In some embodiments, after the cleaning process is performed, an oxide film 103 may remain on the second back side 101b of the first semiconductor pattern 101.

Next, the steps explained above using FIGS. 15 to 20 and FIG. 2 may be performed. Accordingly, the semiconductor device explained above using FIG. 4 may be fabricated.

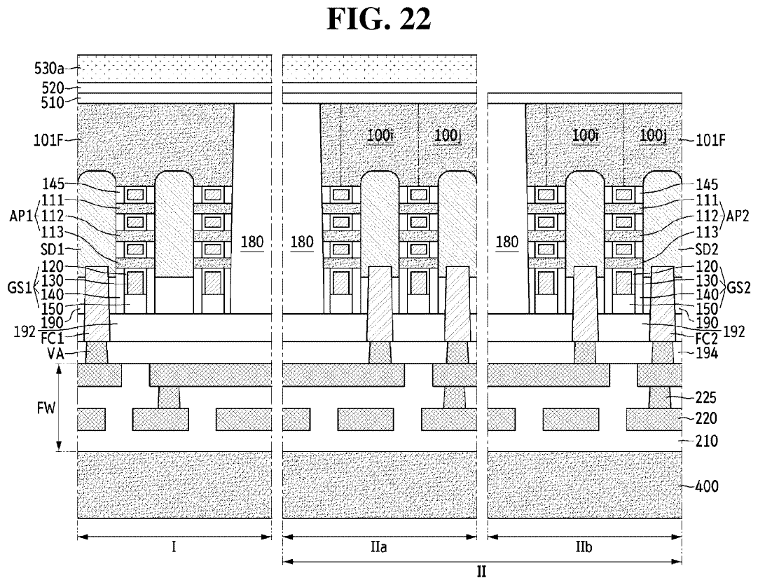

FIGS. 22 to 25 are intermediate step diagrams for explaining a method for fabricating a semiconductor device according to some embodiments. For convenience of explanation, repeated parts of those explained above using FIGS. 1 to 21 will be briefly explained or omitted. For reference, FIG. 22 is an intermediate step diagram for explaining steps after FIG. 12.

Referring to FIG. 22, a first hard mask film 510, a second hard mask film 520, and a second mask pattern 530a are formed on the back side of the base pattern 101F.

The first hard mask film 510, the second hard mask film 520, and the second mask pattern 530a may be sequentially stacked on the back side of the base pattern 101F. The second mask pattern 530a may be patterned to cover the first region I and the first sub-region IIa and expose the second sub-region IIb. The second mask pattern 530a may include, but is not limited to, a photoresist pattern. Next, a patterning process of patterning the second hard mask film 520 using the second mask pattern 530a as an etching mask may be performed. Accordingly, the second hard mask film 520 may cover the first hard mask film 510 of the first region I and the first sub-region IIa, and may expose the first hard mask film 510 of the second sub-region IIb.

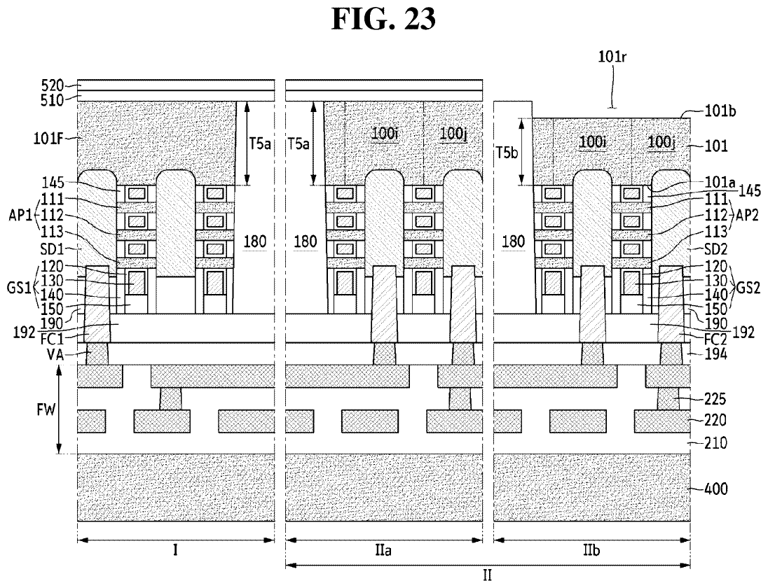

Referring to FIG. 23, a third recess process is performed on the base pattern 101F of the second sub-region IIb.

For example, an etching process of using the second hard mask film 520 as an etching mask may be performed. As the third recess process is performed, the recess 101r may be formed in the base pattern 101F of the second sub-region IIb. In addition, the base pattern 101F of the second sub-region IIb including the recess 101r may form the first semiconductor pattern 101 of the second sub-region IIb. Therefore, a thickness T5b of the first semiconductor pattern 101 of the second sub-region IIb may become smaller than a thickness T5a of the base pattern 101F of the first region I and the first sub-region IIa.

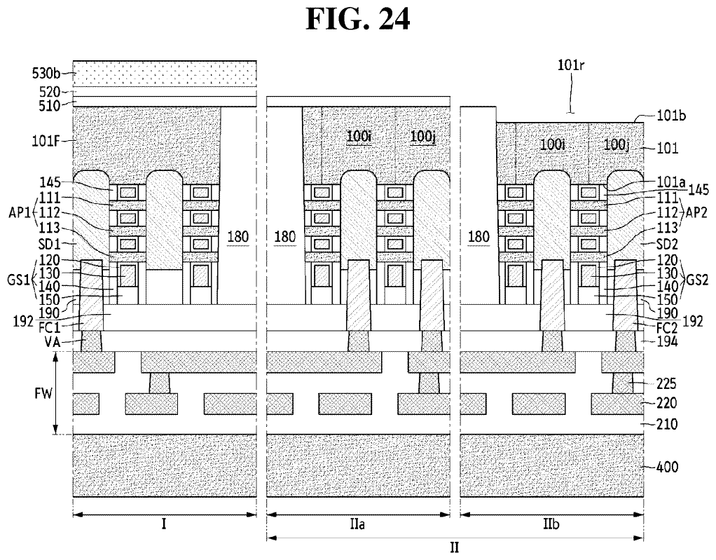

Referring to FIG. 24, a third mask pattern 530b is formed on the second hard mask film 520.

The third mask pattern 530b may be patterned to cover the first region I and expose the second region II. The third mask pattern 530b may include, but is not limited to, a photoresist pattern. Next, a patterning process of patterning the second hard mask film 520 using the third mask pattern 530b as an etching mask may be performed. Accordingly, the second hard mask film 520 may cover the first hard mask film 510 of the first region I, and may expose the first hard mask film 510 of the first sub-region IIa and the first semiconductor pattern 101 of the second sub-region IIb.

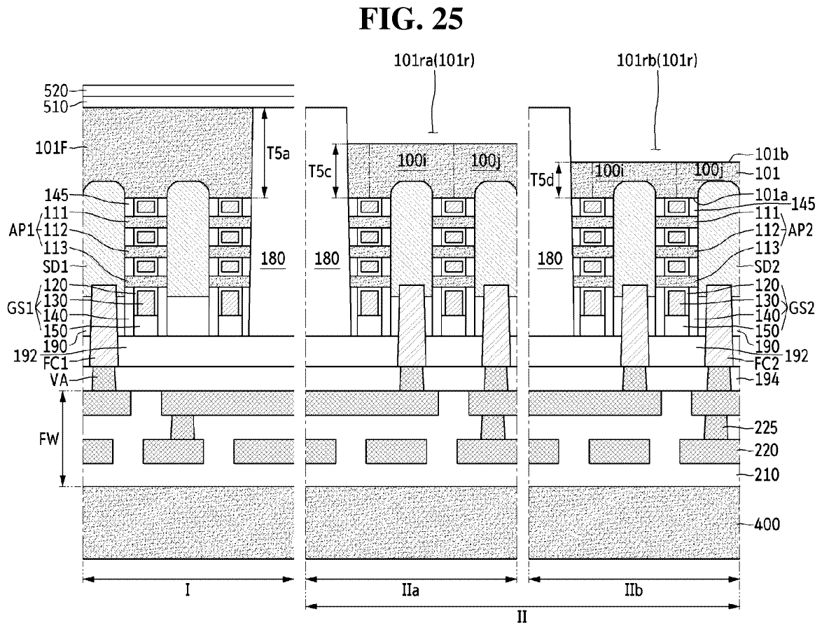

Referring to FIG. 25, a fourth recess process is performed on the base pattern 101F of the first sub-region IIa and the first semiconductor pattern 101 of the second sub-region IIb.

For example, an etching process of using the second hard mask film 520 as an etching mask may be performed. As the fourth recess process is performed, the recess 101r may be formed in the base pattern 101F of the second region II. In addition, the base pattern 101F of the second region II including the recess 101r may form the first semiconductor pattern 101 of the second region II.

The recess 101r may include a first sub-recess 101ra in the first sub-region IIa and a second sub-recess 101rb in the second sub-region IIb. As described above, because the fourth recess process may be performed on the first sub-region IIa, and the third and fourth recess processes may be performed on the second sub-region IIb, a depth of the second sub-recess 101rb may be deeper than a depth of the first sub-recess 101ra. Accordingly, a thickness T5c of the first semiconductor pattern 101 of the first sub-region IIa may become smaller than a thickness T5a of the base pattern 101F of the first region I, and a thickness T5d of the first semiconductor pattern 101 of the second sub-region IIb may become smaller than the thickness T5c of the first semiconductor pattern 101 of the first sub-region IIa.

Next, the steps explained above using FIGS. 15 to 20 and FIG. 2 may be performed. Accordingly, the semiconductor device explained above using FIG. 7 may be fabricated.

In some embodiments, a method for fabricating a semiconductor device including different first and second regions may include forming a base pattern in the first region and the second region, forming, on a front side of the base pattern in the first region, a first active pattern, a first gate structure intersecting the first active pattern, and a first source/drain region connected to the first active pattern on a sidewall of the first gate structure, forming a mask pattern on a back side of the base pattern in the first region, forming a recess in the base pattern of the second region using the mask pattern as an etching mask, forming a buried pattern in the recess, removing at least a part of the base pattern in the first region using the buried pattern as an etching mask, forming an insulating pattern that fills at least a part of a region where the base pattern was removed, forming a back source/drain contact that penetrates the insulating pattern and is connected to the first source/drain region, and forming a backside wiring structure on the insulating pattern and the buried pattern, the backside wiring structure being connected to the back source/drain contact.

In some embodiments, the method may further include forming, in the recess, a liner film and a buried insulating film that are sequentially stacked.

In some embodiments, the method may further include, in the second region including different first and second sub-regions, forming the recess to include a first sub-recess in the first sub-region and a second sub-recess in the second sub-region, the second sub-recess being deeper than the first sub-recess.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above are not restrictive but illustrative in all respects.

What is claimed is:

1. A semiconductor device which includes a first region and a second region that are different from one another, the semiconductor device comprising:
a substrate which includes an insulating pattern in the first region, and a first semiconductor pattern in the second region;
a separation pattern which separates the insulating pattern and the first semiconductor pattern, between the insulating pattern and the first semiconductor pattern;
a first active pattern on an upper surface of the insulating pattern;
a first gate structure which intersects the first active pattern;
a first source/drain region which is connected to the first active pattern, on a sidewall of the first gate structure;
a second active pattern on an upper surface of the first semiconductor pattern;
a second gate structure which intersects the second active pattern;
a buried pattern on a lower surface of the first semiconductor pattern;
a backside wiring structure on a lower surface of the insulating pattern and on a lower surface of the buried pattern; and
a back source/drain contact which penetrates the insulating pattern, and connects the first source/drain region and the backside wiring structure,
wherein the buried pattern includes a liner film extending along profiles of the lower surface of the first semiconductor pattern and the sidewall of the separation pattern, and a buried insulating film on the liner film.

2. The semiconductor device of claim 1,
wherein a thickness of the insulating pattern is greater than a thickness of the first semiconductor pattern.

3. The semiconductor device of claim 1,
wherein the upper surface of the insulating pattern and the upper surface of the first semiconductor pattern are coplanar with one another.

4. The semiconductor device of claim 1,
wherein the substrate further includes a second semiconductor pattern between the insulating pattern and the first active pattern.

5. The semiconductor device of claim 4,
wherein a thickness of the first semiconductor pattern is greater than a thickness of the second semiconductor pattern.

6. The semiconductor device of claim 4,
wherein the upper surface of the first semiconductor pattern and the upper surface of the second semiconductor pattern are coplanar with one another.

7. The semiconductor device of claim 1, further comprising:
a second source/drain region connected to the second active pattern, on the sidewall of the second gate structure.

8. The semiconductor device of claim 7,
wherein the first semiconductor pattern includes an impurity region connected to the second source/drain region.

9. The semiconductor device of claim 1, further comprising:
an oxide film including an oxide of the first semiconductor pattern, between the first semiconductor pattern and the liner film.

10. The semiconductor device of claim 1,
wherein a width of the separation pattern decreases toward the backside wiring structure.

11. The semiconductor device of claim 1,
wherein the liner film includes an aluminum oxide film.

12. The semiconductor device of claim 1,
wherein the buried insulating film includes a silicon nitride film.

13. A semiconductor device which includes a first region and a second region that are different from one another, the semiconductor device comprising:
a substrate which includes an insulating pattern in the first region, a semiconductor pattern in the second region, and a field insulating film that covers at least a part of a sidewall of the insulating pattern and at least a part of a sidewall of the semiconductor pattern;
a first active pattern on an upper surface of the insulating pattern;
a first gate structure which intersects the first active pattern;
a source/drain region which is connected to the first active pattern, on a sidewall of the first gate structure;
a second active pattern on an upper surface of the semiconductor pattern;
a second gate structure which intersects the second active pattern;
a buried pattern on a lower surface of the semiconductor pattern;
a backside wiring structure on a lower surface of the insulating pattern, a lower surface of the field insulating film, and a lower surface of the buried pattern; and
a back source/drain contact which penetrates the insulating pattern, and connects the source/drain region and the backside wiring structure,
wherein the buried pattern includes a liner film extending along profiles of a lower surface of the semiconductor pattern and a sidewall of the field insulating film, and a buried insulating film on the liner film.

14. The semiconductor device of claim 13,
wherein the lower surface of the field insulating film and the lower surface of the buried pattern are coplanar with one another.

15. The semiconductor device of claim 13,
wherein an upper part of the semiconductor pattern protrudes above an upper surface of the field insulating film.

16. The semiconductor device of claim 13,
wherein the upper part of the insulating pattern protrudes above the upper surface of the field insulating film.

17. A semiconductor device which includes a first region and a second region that are different from one another, the semiconductor device comprising:
a substrate which includes an insulating pattern in the first region, and a semiconductor pattern in the second region;
a first active pattern on an upper surface of the insulating pattern;
a first gate structure which intersects the first active pattern;
a source/drain region which is connected to the first active pattern, on a sidewall of the first gate structure;
a second active pattern on an upper surface of the semiconductor pattern;
a second gate structure which intersects the second active pattern;
a buried pattern on a lower surface of the semiconductor pattern;
a backside wiring structure on a lower surface of the insulating pattern and on a lower surface of the buried pattern; and
a back source/drain contact which penetrates the insulating pattern, and connects the source/drain region and the backside wiring structure,
wherein the second region includes a first sub-region and a second sub-region that are different from one another, and
a thickness of the semiconductor pattern of the first sub-region is greater than a thickness of the semiconductor pattern of the second sub-region.

18. The semiconductor device of claim 17,
wherein a thickness of the buried pattern of the first sub-region is smaller than a thickness of the buried pattern of the second sub-region.

19. The semiconductor device of claim 17,
wherein the buried pattern includes a liner film and a buried insulating film which are sequentially stacked on a lower surface of the semiconductor pattern.

20. The semiconductor device of claim 19, further comprising:
a separation pattern between the insulating pattern and the semiconductor pattern, the separation pattern separating the insulating pattern and the semiconductor pattern,
wherein the substrate further includes a field insulating film which covers at least a part of a sidewall of the insulating pattern and at least a part of a sidewall of the semiconductor pattern, and
the liner film extends along profiles of the lower surface of the semiconductor pattern, a sidewall of the separation pattern, and a sidewall of the field insulating film.
